(19) United States
(12) Patent Application Publication
(10) Pub. No.: US 2007/0235848 A1
(43) Pub. Date: Oct. 11, 2007

(54) Substrate having conductive traces isolated by laser to allow electrical inspection

(76) Inventors: Chih-Chin Liao, Yuanlin (TW); Cheemen Yu, Madison, WI (US); Hem Takiar, Fremont, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/392,236

(22) Filed: Mar. 29, 2006

(51) Int. Cl. H01L 23/48; H01L 21/00

(52) U.S. Cl. 257/678; 438/940; 438/106; 438/125; 257/692

(57) ABSTRACT

A semiconductor die substrate panel, and method of forming same, are disclosed wherein plating bars are severed for example by a laser after electroplating of the substrate. Severing the plating bars allows electrical testing of the substrate prior to attachment of electronic components.

### BACKGROUND OF THE INVENTION

1. Field of the Invention

Embodiments of the present invention relate to a semiconductor die substrate panel, and method of forming same, wherein plating bars are severed to allow electrical test of the substrate prior to attachment of electronic components.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid, dielectric base having a conductance pattern, generally of copper or copper alloy, etched on respective sides. Electrical connections are formed between the die and the conductance pattern(s), and the conductance patterns(s) provide an electric lead structure for communication between the die and an external electronic system. Once electrical connections between the die and substrate are made, the assembly is then typically encased in a molding compound to form a protected semiconductor package.

While the copper conductance patterns may be etched to high precision, the poor corrosion properties of copper make it undesirable for certain applications. In the presence of moisture, air and chlorine, bare copper is readily tarnished, making it unsuitable for subsequent soldering and die attach operations. Similarly, certain packages, such as land grid array (LGA) and ball grid array (BGA) packages, include contact fingers formed on a lower surface of the package and exposed outside of the package for establishing electrical connection between the package and an external electronic device. If the contact fingers were formed of bare copper, tarnishing and corrosion would damage the electrical conduction properties of the fingers over time.

It is therefore known to plate copper leads at their solder and/or through-hole points, as well as at the contact fingers. Various plating processes are known for applying a thin film of resistive material, such as tin, tin-lead, nickel or gold. In one such process, a resistive material such as gold may be selectively plated onto the conductance pattern in an electroplating process. Prior art FIG. 1 shows a substrate panel 22 including a plurality of conductance patterns on which will be formed a plurality of integrated circuits. An electroplating process may result in a plurality of gold plating tails 20 on the substrate panel 22. The plating tails 20 may terminate at solder pads 24, through-holes 26, and contact fingers 28 provided for external electrical communication. Not all of the plating tails 20, pads 24 and fingers 28 are numbered in FIG. 1. Plating tails 20 and solder pads 24 shown in dashed lines in FIG. 1 are located on the underside of substrate 22. The substrate 22 further includes plating bars 30 for shorting together the various tails 20, pads 24, through-holes 26 and fingers 28, thus allowing the plating of all pads 24, holes 26 and fingers 28 during the electroplating process.

The plating bars 30 advantageously short together the electrical connections for the plating process. However, while the electrical connections are shorted together, it is not possible to perform electrical testing of the substrate. In particular, it is desirable to test the electrical performance of a substrate, for example in an automatic electrical inspection (AEI), prior to surface mounting the various electronic components thereon. Such electrical inspection would ensure the conductance patterns on the substrate are properly formed and operating correctly.

In certain semiconductor package fabrication processes, the plating bars are not severed until the encapsulated substrate panel is singulated into the individual semiconductor packages. In these processes, AEI of the substrate is not possible. In other semiconductor package fabrication practices, it is known to perform an “etch back” process where the plating bars are severed after the electroplating process so that each solder pad, through-hole and/or contact finger is electrically isolated from each other, thus allowing electrical test of the substrate.

However, there are drawbacks to known etch back processes. First, the etch back process requires a large number of process steps and adds to the overall cost and complexity of the fabrication process. After formation of the conductance patterns and formation and plating of the through-holes, an etch back process may typically include the following steps:
a) laminate a photoresist dry film or the like onto the upper and lower surfaces of the substrate panel;
b) develop the dry film to expose the surfaces of the panel to be electroplated;
c) electroplate the exposed surfaces exposed in step b);
d) strip the dry film;
e) laminate solder mask over the surfaces of the panel;
f) develop portions of the solder mask to expose electroplated surfaces and portions of the plating bars to be etched;
g) etch the exposed portions of the plating bars to thereby electrically isolate the solder pads, through-holes and/or contact fingers.

A portion of the substrate panel 22 after the etch back process is completed is shown in prior art FIG. 2. The above-described steps result in etched areas 40 which sever the plating bar 30 at the contact fingers 28 and/or other traces to electrically isolate the contact fingers and/or other electrical connections on the conductance patterns of the substrate panel 22.

In addition to the additional steps required for the etch back process, the size of the openings achievable with etching is on the order of 150 (μm) or larger. The problem is that the boundary area including the plating bars 30 between adjoining integrated circuit areas on substrate 22 has a small dimension, for example 300 μm. Thus, it may happen that an etched area 40 does not fit entirely within the boundary between adjoining integrated circuit areas, and in fact protrudes into the actual integrated circuit area.

### SUMMARY OF THE INVENTION

Embodiments of the invention relate to a semiconductor die substrate panel, and method of forming same, wherein plating bars are severed to allow electrical test of the substrate prior to attachment of electronic components. During fabrication of the substrate panel, after conductance patterns and through-holes have been formed, the panel may be laminated with a solder mask. The solder mask may then be developed to expose the electrical terminals, which may then be plated in, for example, a known electroplating process.

After the substrate panel is electroplated, each of the electrical terminals may be electrically isolated in accordance with the present invention to allow electrical testing of the substrate prior to surface mounting of the electronic components. In one embodiment, electrical isolation may be accomplished with a laser forming holes through the plating bars to sever the plating bars and electrically isolate the electrical terminals formerly shorted together by the plating bars.

The holes formed by the laser may be at the junctions of the plating bars and the plating tails, though the holes may be formed elsewhere on the plating bars to electrically isolate the electrical terminals. In a further embodiment, the holes may be formed through the plating tails which connect the electrical terminals to the plating bar.

Severing the plating bars using a laser capable of making small holes provides advantages over conventional etch back processes in that the small diameter holes formed according to the present invention do not protrude into the space on which the integrated circuit is formed on the substrate. Moreover, the method of isolating the electrical terminals according to the present invention may be performed in fewer steps than etch back processes. The fewer steps according to the present invention simplify the substrate fabrication process and reduces the overall cost of production.

After the electrical terminals have been electrically isolated from each other by the lasing step of severing the plating bar, electrical testing such as AEI may be performed. Such electrical testing can identify defective panels prior to surface mounting of the electronic components, to reduce costs and improve yield.

### BRIEF DESCRIPTION OF THE DRAWINGS

FIG. 1 is a prior art top view of a semiconductor die substrate panel including a plurality of integrated circuit areas and a grid of plating bars.

FIG. 2 is an enlarged top view of a substrate panel showing a single integrated circuit area and openings formed in the plating bar by conventional etch back techniques.

FIG. 3 is a cross-sectional side view of a portion of a substrate panel during fabrication.

FIG. 4 is a flowchart of a process for fabricating a substrate panel according to the present invention.

FIGS. 5-8 are cross-sectional side views of a portion of a substrate panel at various stages of fabrication according to the present invention.

FIG. 9 is an enlarged top view of a substrate panel showing a single integrated circuit area and openings formed in the plating bar according to an embodiment of the present invention.

FIG. 10 is an enlarged top view of a substrate panel showing a portion of a single integrated circuit area and openings formed in the plating bar according to an alternative embodiment of the present invention.

FIG. 11 is a cross-sectional side view of a semiconductor package including a substrate panel formed according to an embodiment of the present invention.

FIG. 12 is a rear view of a flash memory device formed with the semiconductor package of FIG. 11.

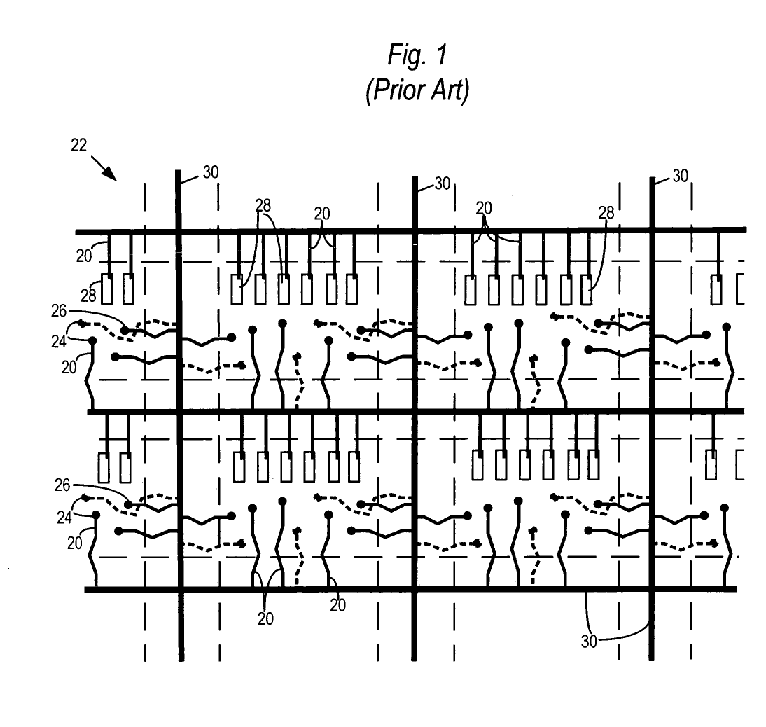

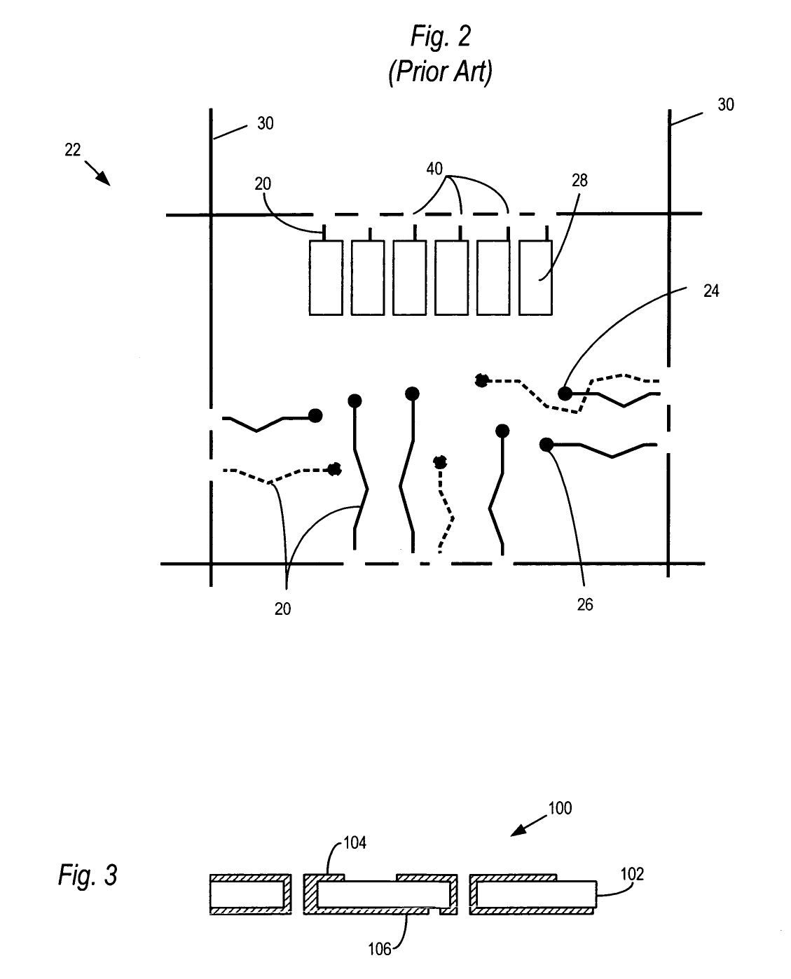

### DETAILED DESCRIPTION

Embodiments of the invention will now be described with reference to FIGS. 3 through 12, which relate to a semiconductor die substrate panel, and method of forming same, wherein plating bars are severed to allow electrical test of the substrate prior to attachment of electronic components. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

Referring initially to the side view of FIG. 3, there is shown a portion of a substrate panel 100. The portion of substrate panel 100 shown may be for a single integrated circuit. It is understood that a plurality of such portions may be repeated on panel 100 to provide the locations of a plurality of such integrated circuits.

Substrate panel 100 may be formed of a core 102, having a top and bottom conductive layer 104 and 106, respectively. The core 102 may be formed of various dielectric materials such as for example, polyimide laminates, epoxy resins including FR4 and FR5, bismaleimide triazine (BT), and the like. Although not critical to the present invention, the core may have a thickness of between 40 μm to 200 μm, although the thickness of the core may vary outside of that range in alternative embodiments. The core may be ceramic or organic in alternative embodiments.

The conductive layers 104, 106 may be formed of copper or copper alloys, plated copper or plated copper alloys, Alloy 42 (42Fe/58Ni), copper plated steel, or other metals and materials known for use on substrates. The layers may have a thickness of about 10 μm to 24 μm, although the thickness of the layers may vary outside of that range in alternative embodiments.

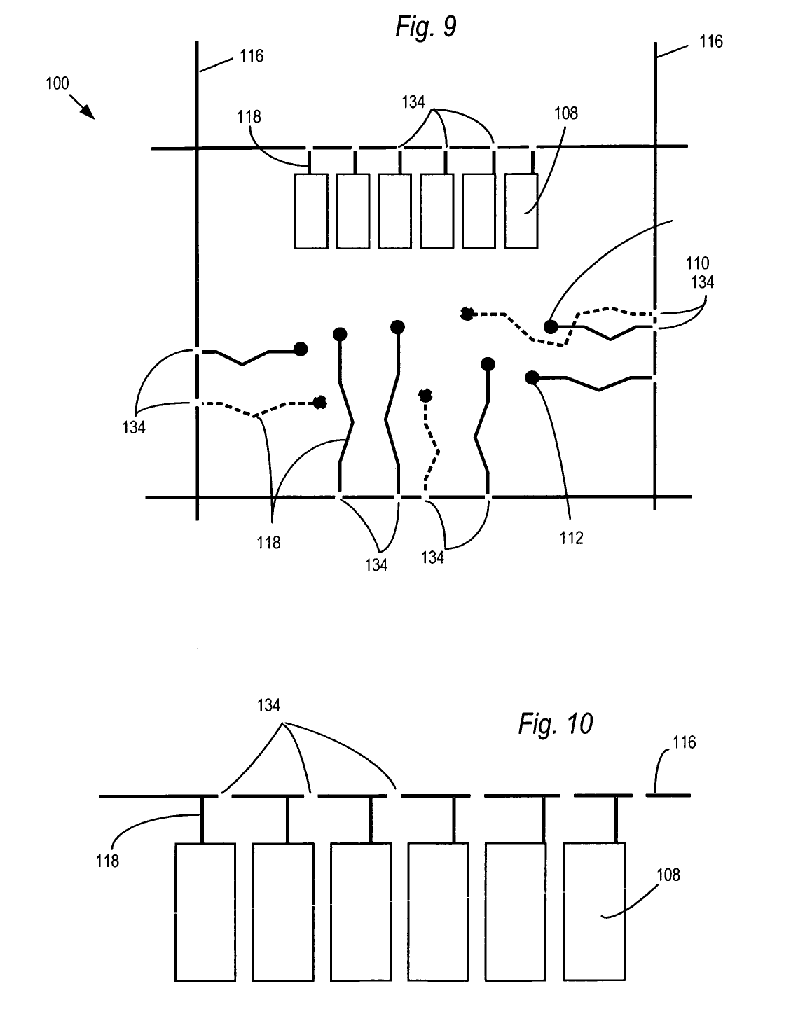

As seen in the cross-sectional view of FIG. 3 and the top view of FIG. 9, one or both of the conductive layers 104, 106 may be etched in a known photolithography process with a conductance pattern for signal and power communication. The conductance pattern on one side of the substrate panel 100 may include contact fingers 108 (FIG. 9) for establishing electrical connection between the finished semiconductor package and an external electronic device. The conductance pattern on one or both sides of the substrate panel 100 may include solder pads 110 where electrical contacts for surface mounted components such as semiconductor die are soldered to the substrate panel. Through-holes 112 may further be defined in the substrate panel 100 for electrical communication between the conductance patterns on opposed surfaces of the substrate panel. The conductance pattern on one or both sides of the substrate panel 100 may further include plating bars 116 and plating tails 118 used in a plating process as explained hereinafter.

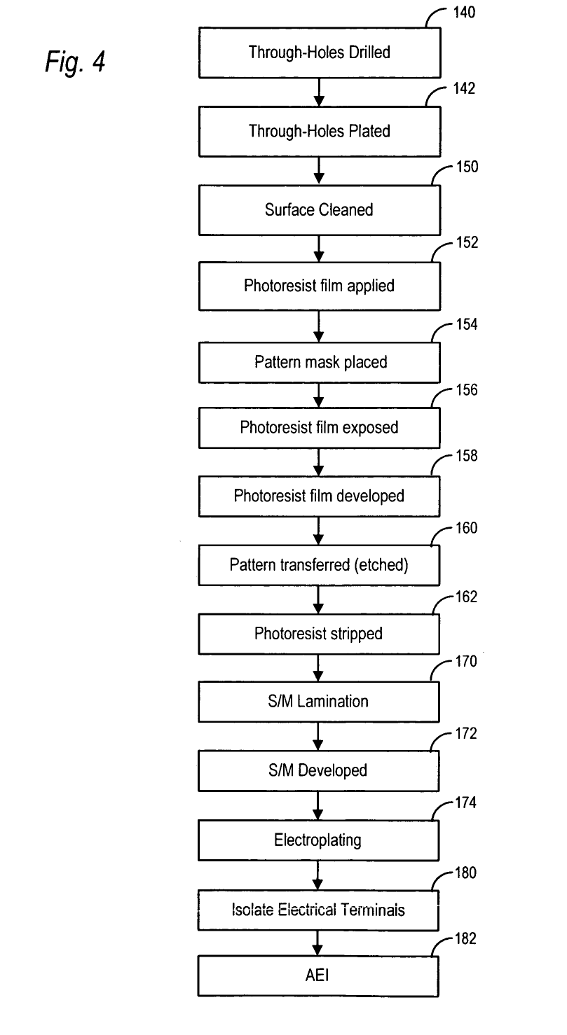

One process for forming the conductance patterns including contact fingers 108, solder pads 110, through-holes 112, plating bars 116 and plating tails 118 on the substrate panel 100 is explained with reference to the flowchart of FIG. 4. The through-holes 112 may be formed in the substrate panel 100 by drilling holes through the panel 100 in a step 140, and plating or filling the holes with a conductor by known processes in step 142. The surfaces of the conductive layers may be cleaned in a step 150. A photoresist film is then applied over the surfaces of the conductive layers in step 152. A pattern mask containing the outline of the electrical conductance pattern may then be placed over the photoresist film in step 154. The photoresist film is exposed (step 156) and developed (step 158) to remove the photoresist from areas on the conductive layers that are to be etched. The exposed areas are next etched away using an etchant such as ferric chloride in step 160 to define the conductance patterns on the core. Next, the photoresist is removed in step 162. Other known methods for forming the conductance pattern on substrate panel 100 are contemplated. The result of the steps 140 through 162 is the substrate panel 100 shown in FIG. 3.

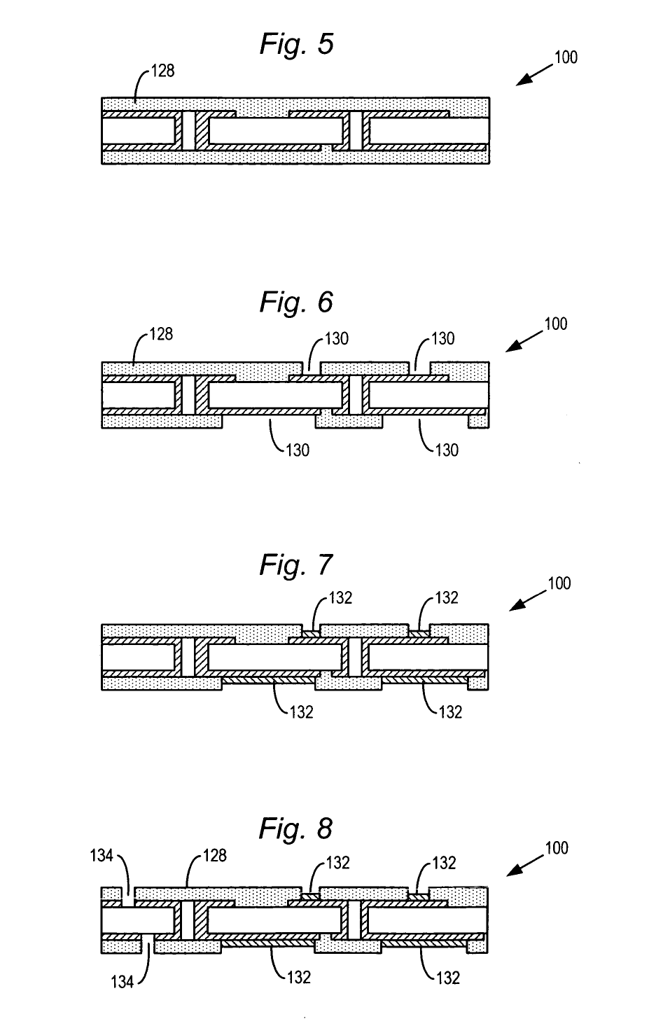

After formation of the conductance pattern and through-holes on the substrate panel 100, the panel 100 may be laminated with a solder mask 128 as shown in FIG. 5 and as indicated in step 170. Solder mask 128 isolates and protects the electrical conductance patterns defined on the substrate. In step 172, the solder mask 128 may be developed to expose areas 130 on the conductance pattern as shown in FIG. 6. Areas 130 may be the electrical terminals (contact fingers 108, solder pads 110 and the through-holes 112) which are to be plated.

In step 174, the areas 130 may be plated with a layer of resistive metal 132 as shown in FIG. 7 in a known electroplating process. The electrical terminals of the conductance pattern may be plated with a metal film, such as for example gold, though other metals, including tin, tin-lead and nickel may be plated onto the conductance pattern(s) in alternative embodiments. In one embodiment of a process for plating the substrate panel 100, the panel may be immersed in a plating bath including metal ions in an aqueous solution. A current is then supplied to the plating bars 116, which current travels through the plating bars 116, through the tails 118 and to the solder pads 110, through-holes 112 and/or contact fingers 108. When the current is delivered, plating bars 116, tails 118, pads 110, through-holes 112 and fingers 108 are electrified and a charge is created at their surface. The metal ions are attracted to the electrified and charged metal areas. A thin film of metal is thus plated onto the shorted areas of the conductance pattern. The thickness of the plated film may vary, but in embodiments may be between 10 μm and 50 μm, though it may be thinner or thicker than that in alternative embodiments. Other known methods for electroplating a metal film on the conductance pattern(s) may be used in alternative embodiments.

After the substrate panel 100 is electroplated, each of the electrical terminals may be electrically isolated in step 180 in accordance with the present invention to allow electrical testing of the substrate prior to surface mounting of the electronic components. In one embodiment, the electrical isolation step 180 may be accomplished by a laser forming holes through the plating bars 116 to sever the plating bars and electrically isolate the electrical terminals formerly shorted together by the plating bars. As shown in FIG. 8, a laser may form holes 134 through the solder mask 128 and the plating bars provided in layers 104 and/or 106 to thereby sever the plating bars 116.

FIG. 9 is a partial view of a substrate panel 100 showing a single integrated circuit area. Substrate panel 100 may include a plurality of such integrated circuit areas. As shown in FIG. 9, the holes 134 may be formed at the junction of the plating bars 116 and the plating tails 118, to thereby electrically isolate all (or some) of the contact fingers 108, solder pads 110 and the through-holes 112 from each other. Those of skill in the art will appreciate that the holes 134 may be formed at a variety of additional or alternative positions along the plating bars 116 to electrically isolate the contact fingers 108, solder pads 110 and/or the through-holes 112 from each other as desired. For example, in one alternative embodiment shown in FIG. 10, the holes 134 are positioned on the plating bar 116, between plating tails 118. In a further embodiment, the holes 134 may alternatively or additionally be formed through the plating tails 118 to sever the plating tails and electrically isolate the associated electrical terminal.

The step 180 may be performed by a laser upon locating the substrate panel on a fixture associated with the laser and in a known position relative to the laser. Substrate panel 100 may include fiducial and/or optical holes allowing the position of the substrate panel to be identified on the fixture. Once the position of the panel 100 is identified on the fixture, the holes may be lased in the desired location on the panel 100 by the laser.

It is understood that the conductance patterns, through-holes and the locations of the electroplated layers 132 and lased holes 134 shown in FIGS. 3, 5, 6, 7, 8 and/or 9 are by way of example only to illustrate the principles of the present invention. Those of skill in the art would appreciate that a wide variety of other patterns, electroplated layers and lased holes may be formed in substrate panel 100 according to the present invention. Not all of the contact fingers 108, solder pads 110, through-holes 112, plating bars 116 and plating tails 118 are numbered in FIG. 9. Plating tails 118 and solder pads 110 shown in dashed lines in FIG. 9 are located on the underside of the substrate panel. Moreover, the panel 100 may include more solder pads, through-holes and/or contact fingers than shown. Although not shown, some of the electrical terminals may be formed electrically shorted to each other, and the electrical coupling between such terminals subsequently broken with a lased hole 134 to isolate each terminal from each other according to the present invention.

A variety of lasers are known for use in severing the plating bars 116 or other electrical connections as described above. Examples include CO₂ lasers, UV lasers, YBO₄ lasers, Argon lasers, etc. Such lasers are manufactured for example by Rofin-Sinar Technologies of Hamburg, Germany. The use of a laser has the advantage over the etch back process described in the Background of the Invention section in that holes 134 may have smaller diameters than that achievable with etching. In embodiments, holes 134 may be formed with a diameter of about 120 μm or less. It is understood that holes 134 may be larger than 120 μm in alternative embodiments. Moreover, while holes of this size may currently be formed using a laser, it is understood that other processes may be used which are capable of forming holes 134 as described above.

Severing plating bars 116 with small holes provides advantages over the etch back processes described in the Background of the Invention section in that the small diameter holes of the present invention do not protrude into the space on which the integrated circuit is formed on the substrate. Moreover, the method of isolating the electrical terminals according to the present invention may be performed in fewer steps than etch back processes. As described in the Background of the Invention section, etch back processes are performed by the steps of:
a) laminating a photoresist dry film or the like onto the upper and lower surfaces of the substrate panel;
b) developing the dry film to expose the surfaces of the panel to be electroplated;
c) electroplating the exposed surfaces exposed in step b);
d) stripping the dry film;
e) laminating solder mask over the surfaces of the panel;
f) developing portions of the solder mask to expose electroplated surfaces and portions of the plating bars to be etched;
g) etching the exposed portions of the plating bars to thereby electrically isolate the solder pads, through-holes and/or contact fingers.
   By contrast, the present invention is able to isolate electrical terminals in a substrate panel by the steps of:
a) laminating solder mask over the surfaces of the panel;
b) developing portions of the solder mask to expose portions of substrate to be plated;
c) electroplating the exposed surfaces exposed in step b);
d) severing portions of the plating bars with a laser or the like to electrically isolate the solder pads, through-holes and/or contact fingers.
   While etch back processes may be performed by alternative methods, the alternative methods still require greater steps than in the present invention. The fewer steps according to the present invention simplify the substrate fabrication process and reduce the overall cost of production.

Referring again to the flowchart of FIG. 4, after the electrical connections for plating have been broken, the substrate panel 100 may be electrically tested in step 182, for example by AEI. Such electrical testing can detect open connections and/or shorts in substrate panel 100, thus identifying defective panels prior to surface mounting of the electronic components. Identifying defective substrate panels prior to surface mounting of electronic components improves yields and reduces overall fabrication costs.

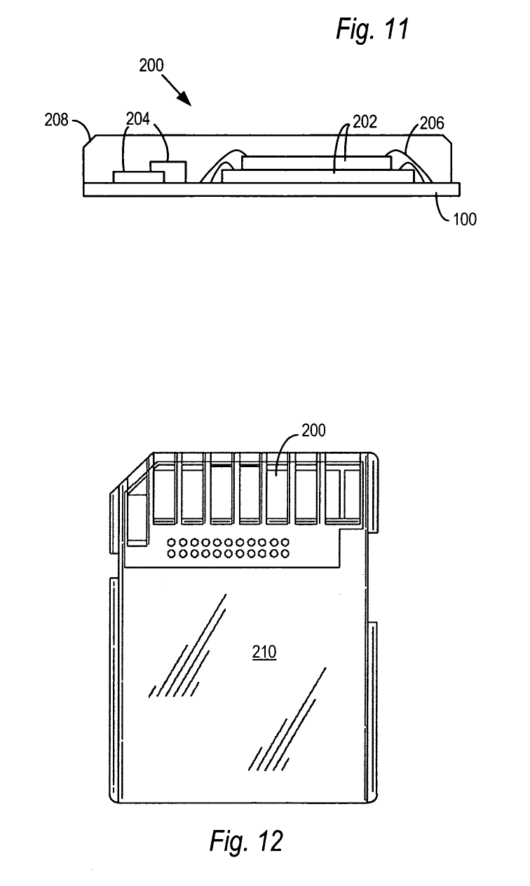

Those substrate panels which pass the electrical testing may then be used for semiconductor package fabrication. Referring to FIG. 11, electronic components may be mounted on substrate panel 100 to form a semiconductor package 200. In particular, one or more semiconductor die 202 and passive devices 204 may be mounted on the substrate panel 100. Although not critical to the present invention, the semiconductor die 202 may be a flash memory chip (NOR/NAND), SRAM or DDT, and/or a controller chip such as an ASIC. Other silicon chips are contemplated.

The one or more die 202 may be electrically connected to the substrate panel 100 by wire bonds 206 soldered at the plated solder pads 110 in a known wire bond process. Thereafter, the substrate and die may be encased within a molding compound 208 in a known encapsulation process, and thereafter singulated to form a finished semiconductor die package 200.

FIG. 12 is a rear view of a flash memory device 210 in which the semiconductor package 200 may be used. The flash memory device 210 may be an SD Card, a Compact Flash, a Smart Media, a Mini SD Card, an MMC, an xD Card, a Transflash or a Memory Stick. Other devices are contemplated.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of fabricating a substrate for a semiconductor die package comprising the steps of:
(a) shorting together a plurality of electrical terminals on the substrate to facilitate electroplating the electrical terminals; and
(b) severing an electrical connection between the electrical terminals with a laser prior to mounting a semiconductor die on the substrate.

2. A method as recited in claim 1, further comprising a step (c) of testing the electrical function of the substrate prior to mounting a semiconductor die on the substrate.

3. A method as recited in claim 1, wherein said step (b) of severing an electrical connection between the electrical terminals with a laser comprises the step of severing the electrical connection with a hole having a diameter greater than or equal to a width of the electrical connection and lesser than or equal to 120 microns.

4. A method of fabricating a substrate for a semiconductor die package, the substrate including a first electrical terminal electrically connected to a second electrical terminal by an electrical connector formed on the substrate, the method comprising the steps of:
(a) electroplating the first and second electrical terminals; and
(b) lasing a hole into the substrate, through the electrical connector, to sever the electrical connector prior to mounting a semiconductor die on the substrate.

5. A method as recited in claim 4, wherein said step (a) of electroplating the first and second electrical terminals comprises the steps of electroplating at least one contact finger formed on the substrate.

6. A method as recited in claim 4, wherein said step (a) of electroplating the first and second electrical terminals comprises the steps of electroplating at least one solder pad formed on the substrate.

7. A method as recited in claim 4, wherein said step (b) of lasing a hole through the electrical connector to sever the electrical connector comprises the step of severing a plating bar formed on the substrate.

8. A method as recited in claim 7, wherein said step of severing a plating bar formed on the substrate comprises the step of severing the plating bar at a junction of the plating bar and a plating tail connected to one of the first and second electrical terminals.

9. A method as recited in claim 7, wherein said step of severing a plating bar formed on the substrate comprises the step of severing the plating bar at a position between the junctions of first and second plating tails with the plating bar, the first and second plating tails connected to the first and second electrical terminals.

10. A method as recited in claim 4, wherein said step (b) of lasing a hole through the electrical connector to sever the electrical connector comprises the step of severing a plating tail formed on the substrate.

11. A method as recited in claim 4, wherein said step (b) of lasing a hole through the electrical connector to sever the electrical connector comprises the step of forming a hole through a layer of solder mask formed on the substrate and a conductive layer formed on the substrate.

12. A method of fabricating a substrate for a semiconductor die package, comprising the steps of:
(a) defining a plurality of electrical terminals on the substrate;
(b) defining an electrical connector shorting together at least two of the electrical terminals defined in said step (a);
(c) laminating a solder mask over the electrical terminals and electrical connector of the substrate;
(d) developing portions of the solder mask to expose the electrical terminals on the substrate;
(e) electroplating the electrical terminals exposed in said step (c); and
(f) severing the electrical connector defined in said step (b), prior to mounting of a semiconductor device on the substrate, to electrically isolate the at least two electrical terminals defined in said step (a) from each other.

13. A method as recited in claim 12, wherein said step (f) of severing the electrical connector comprises the step of severing the electrical connector with a laser.

14. A method as recited in claim 12, wherein said step (b) of defining an electrical connector shorting together at least two of the electrical terminals comprises the step of defining a plating bar on the substrate.

15. A method as recited in claim 12, wherein said step (b) of defining an electrical connector shorting together at least two of the electrical terminals comprises the step of defining a plating tail on the substrate.

16. A substrate for a semiconductor die package, the substrate comprising:
a first electrical terminal formed on the substrate;
a second electrical terminal formed on the substrate;
a plating bar formed on the substrate for electrically connecting the first electrical terminal to the second electrical terminal;
the substrate formed by a method comprising the steps of:
(a) electroplating the first and second electrical terminals; and
(b) lasing a hole into the substrate, through the plating bar, to sever the electrical connector prior to mounting a semiconductor die on the substrate.

17. A substrate as recited in claim 16, wherein said step (a) of electroplating the first and second electrical terminals comprises the steps of electroplating at least one contact finger formed on the substrate.

18. A substrate as recited in claim 16, wherein said step (a) of electroplating the first and second electrical terminals comprises the steps of electroplating at least one solder pad formed on the substrate.

19. A substrate as recited in claim 16, the substrate further comprising a plating tail for connecting the first electrical terminal to the plating bar, wherein said step of severing the plating bar comprises the step of severing the plating bar at a junction of the plating bar and the plating tail.

20. A substrate as recited in claim 16, the substrate further comprising:
a first plating tail for connecting the first electrical terminal to the plating bar; and
a second plating tail for connecting the second electrical terminal to the plating bar;
wherein said step of severing the plating bar comprises the step of severing the plating bar at a position of the plating bar between a first junction of the plating bar and the first plating tail and a second junction of the plating bar and the second plating tail.
